(19) United States
(12) Patent Application Publication
(10) Pub. No.: US 2025/0079750 A1
(43) Pub. Date: Mar. 6, 2025

(54) HOUSING ARRANGEMENT FOR ELECTRICAL OR ELECTRONIC COMPONENTS

(71) Applicant: Weidmüller Interface GmbH & Co. KG, Detmold (DE)

(72) Inventors: Till SCHMITZ, Detmold (DE); Peter STUCKMANN, Lage (DE)

(21) Appl. No.: 18/756,239

(22) Filed: Jun. 27, 2024

(30) Foreign Application Priority Data
Aug. 28, 2023 (DE) 102023123072.7

(51) Int. Cl. H01R 13/514; H01R 13/627

(52) U.S. Cl. CPC H01R 13/514; H01R 13/6273

(57) ABSTRACT

A housing arrangement includes at least two or more interconnected housings which are stacked together in a stacking direction, and which respectively have at least one receiving space in which one or more electrical and/or electronic components are arranged. The respective housings are each formed in a disc-like manner, have two stacking walls and a number of narrow sides. Adjacent housings of the housing arrangement are connected to one another with at least one or more latching connections, wherein the respective latching connection of at least the middle housing has at least one latching arm. Starting from a connecting region in which it is connected to the respective housing, the latching arm first extends at one of the narrow sides in an arm region parallel to this narrow side. The latching arm has a lug which extends in the stacking direction, and which engages at least partly over an adjacent housing in the stacking direction. The latching arm further has a first latching mechanism for latching on a corresponding second latching mechanism of an adjacently stacked housing.

### BACKGROUND OF THE INVENTION

The present invention relates to a housing arrangement and a printed circuit board plug-in connector or a series terminal with such a housing arrangement.

A wide range of embodiments of housing arrangements made up of stackable housings are known. In the case of many of these housings, the existing construction spaces, in the case of housings which are particularly narrow and small in the stacking direction, are not sufficient to generate sufficiently robust and practically manageable latching connections for firmly connecting the housings with conventional snap-fit connections. In this respect, it would be desirable to further optimize the housings.

### SUMMARY OF THE INVENTION

Accordingly, it is an object of the present disclosure to provide a housing arrangement that has at least two or more interconnected housings which are stacked together in a stacking direction, and which respectively have at least one receiving space in which one or more electrical and/or electronic components are arranged. The respective housings are each formed in a disc-like manner and have two stacking walls and a number of narrow sides, wherein adjacent housings of the housing arrangement are connected to one another with at least one or more latching connections. The respective latching connection, at least of the middle housings, has at least one latching arm. Starting from a connecting region in which it is connected to the respective housing, the latching arm extends at one of the narrow sides firstly in an arm region parallel to this narrow side. The arm region furthermore has a lug which extends in the stacking direction. It engages, at least partly, over an adjacent housing in the stacking direction and has a first latching mechanism for latching on a corresponding second latching mechanism of the adjacently stacked housing.

In one embodiment, the latching arm is longer than if it or a deflectable other latching hook would extend only in the stacking direction. It is thus possible to deflect the latching arm relatively far when latching, which results in more simplified latching. This also achieves relatively high retaining forces of the latching connection without requiring a particularly large amount of construction space in the stacking direction of the respective housing. Accordingly, a housing which is narrow in the stacking direction can be realized despite higher retaining forces.

In particular, the latching arm can be formed longer from the connecting region to the latching aperture than the width of the housings in the stacking direction. In this manner, the latching arm can be raised to securely engage the rear of a relatively high latching hook of the respective adjacent housing.

According to another embodiment, it can be envisaged that the lug has a first latching mechanism including a latching aperture, in particular one, formed like a window, such that it fully penetrates the lug. It can then furthermore be conveniently envisaged that the second latching mechanism of the respective adjacent housing is formed as a protruding latching hook immovably formed on the housing, on the narrow side on which in each case the latching arm is also formed. With this latching mechanism configuration, the great length of the latching arm has a particularly advantageous effect.

According to a further embodiment, it can optionally be envisaged that the respective latching hook has a chamfer for raising the latching arm of the respectively adjacent housing when the housing is pushed together, and a latching edge on which the latching aperture can be engaged. In this manner, the housings can be manually latched together simply by pushing or plugging them together, without a tool being required to latch. In addition, or alternatively, the lug can also have a lateral chamfer which facilitates raising the lug when running onto the latching hook of the adjacent housing.

According to a configuration which is particularly advantageous because it is particularly safe from vibrations, it can furthermore be envisaged that the respective latching arm is formed longer from the connecting region to the latching aperture than the screen width of the housings in the stacking direction.

In yet another embodiment, the housing arrangement has one or more additional, differently formed latching hook connections between the adjacent housings and/or it has one or more mortise joints between the stacked housings, which preferably act in a centering and clamping manner.

In a further embodiment, plug-in connectors or series terminals have a housing arrangement as disclosed herein.

### BRIEF DESCRIPTION OF THE DRAWING

The invention is described in greater detail hereinafter with reference to the drawings. In the drawings:

FIG. 1a is a perspective view of a plug-in connection with a first plug-in connector with a housing arrangement made up of four interconnected housings which are stacked together in a stacking direction, wherein the housing arrangement is closed off towards one side by a cover plate, and with a second corresponding plug-in connector in which the first plug connector is plugged;

FIG. 1b is a plan view of the housing arrangement from FIG. 1a;

FIG. 2a is a perspective view of two individual, middle housings of the housing arrangement of the first plug-in connector from FIG. 1a before the housings are joined together to form a combined unit;

FIG. 2b is a plan view of the arrangement from FIG. 2a;

FIG. 2c is a view of the arrangement from FIG. 2a corresponding to a plane perpendicular to the plane of the page and to line F-F from FIG. 2b;

FIG. 2d is partial enlarged view showing the region D from FIG. 2c;

FIGS. 2e-2h correspond to FIGS. 2a-2d, respectively, but show a state in which the two housings have been fully connected to one another, with FIG. 2e showing an enlarged detail E from FIG. 2g;

FIG. 3a is a perspective view of a housing and a cover plate of the housing arrangement of the first plug-in connector from FIG. 1a before being joined together to form a combined unit, wherein the housing and the cover plate are spaced further apart from one another and do not touch one another;

FIG. 3b is a plan view of the arrangement from FIG. 3a;

FIG. 3c is a side view of the arrangement from FIG. 3a;

FIGS. 3d-3f correspond to FIGS. 3a-3c, respectively, but show a state in which the housing and the cover plate are touching one another but have not yet been fully connected to one another;

FIGS. 3g-3i correspond to FIGS. 3a-3c, respectively, but show a state in which the housing and the cover plate have been fully connected to one another;

FIG. 3j is a partial enlarged view showing region A from FIG. 3f;

FIG. 3k is a partial enlarged view showing region B from FIG. 3i; and

FIG. 3l is a partial perspective view of a region of the right-hand lateral cover plate.

### DETAILED DESCRIPTION

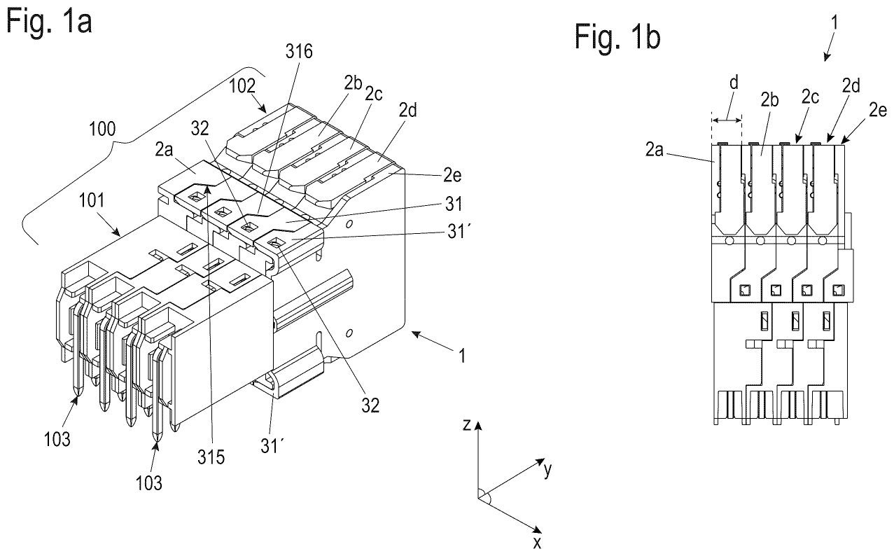

The terms used hereafter such as “top”, “bottom”, “right-hand”, “left-hand”, “horizontal” or “vertical” relate to the depiction of the respective figure. A coordinate system in FIG. 1a is used in each case for further orientation. In the event of a different orientation in the space, this coordinate system moves with it.

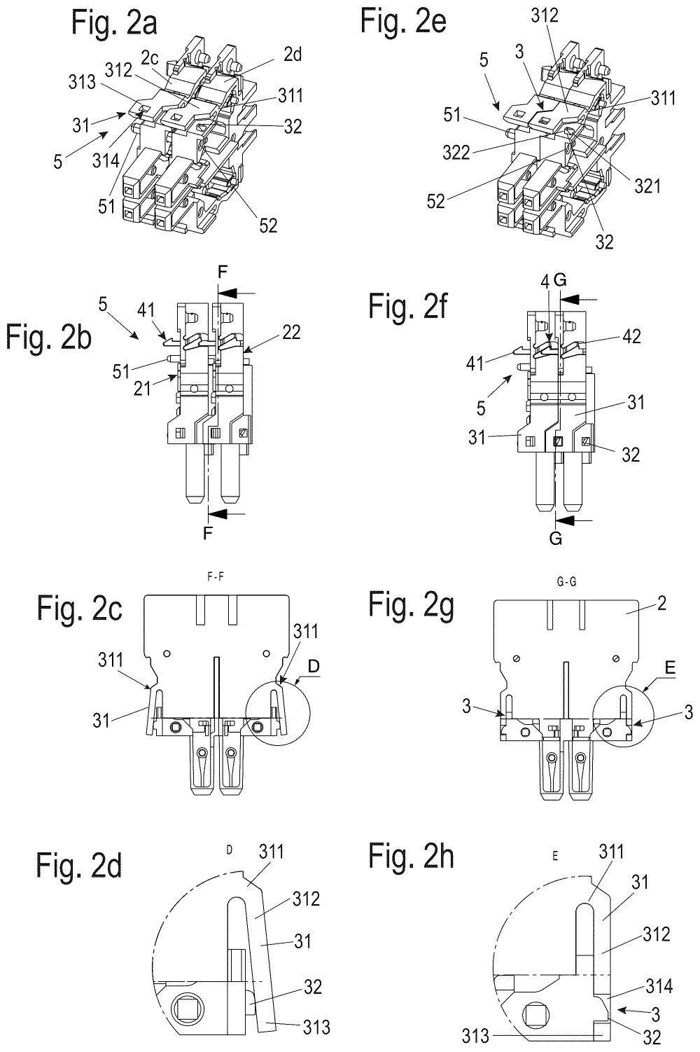

FIGS. 1a and 2b depict a plug-in connection 100 with a first plug-in connector 101 and a second plug-in connector 102. The first plug-in connector 101 can have terminal contacts 103 (which are formed here as 90° solder pins) e.g. for connection to a printed circuit board. The second plug-in connector 102 can have one or more terminal contacts for the connection of conductor ends (not shown here).

The two plug-in connectors 101, 102 have corresponding plugging faces with corresponding plugging contacts which can be plugged together. Such plug-in connections 100 are known per se in terms of their fundamental function and therefore need not be further explained or depicted here.

The disc-like design of the second plug-in connector 102 is further disclosed.

The second plug-in connector 102 has a housing arrangement 1 made up of a number of stacked-together housings 2a-2d and an optional cover plate 2e. The housing arrangement 1 here has four housings 2a, 2b, 2c and 2d and one cover plate 2e. The housing arrangement 1 could also consist of a different number of housings 2, though it preferably has at least two housings 2. Moreover, the housings 2 are preferably made of an isolating plastic.

The housings 2a-2d can be formed as housings for receiving electrical and/or electronic components. The lateral cover plate 2e does not have any such components and serves here only as a type of lateral cover of the housing 2d.

The housing 2b has a first side wall, which in the case of the middle housings is a first stacking wall 21, and a second side wall, which can be a second stacking wall 22.

In the stacked state, the first stacking wall 21 rests on the opposing stacking wall 22 of an adjacent housing 2c.

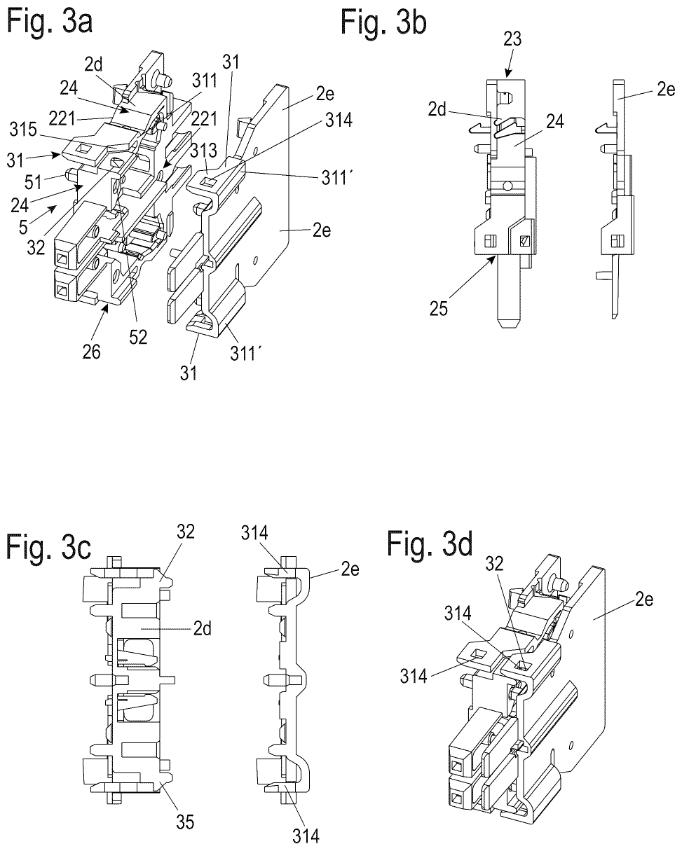

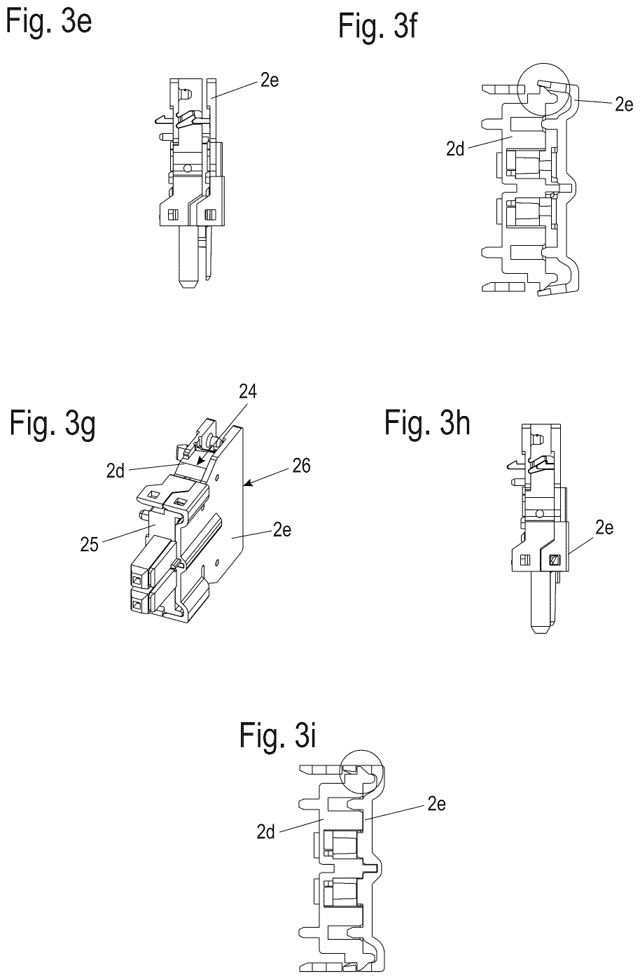

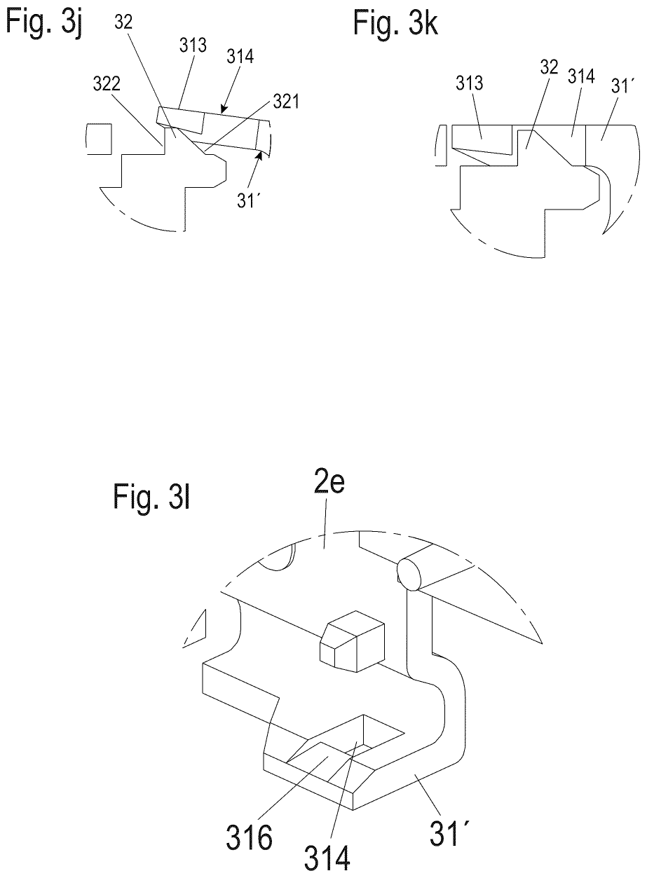

The second stacking wall 22 has a housing aperture 221 (FIG. 3a, 3b). In this regard, the first stacking wall 21, which is preferably formed to be more closed, of the housing 2b to be stacked also acts as a cover of the housing aperture 221 of the adjacent, already stacked housing 2a. As a result, a closed receiving space can be formed respectively by two adjacent stacked-together housings 2a, 2b, 2c, 2d (see also FIG. 2b, FIG. 2d, FIG. 2f in this regard).

The cover plate 2e covers the housing aperture 221 of the last stacked housing 2d (see FIG. 3a) in the housing arrangement 1 of stacked housings 2a, 2b.

Through this design of the housing 2a-2d there arises a narrow design of the individual housing 2a, 2b, 2c, 2d with a screen width d (FIG. 1b), such that a relatively large number of housings 2a, 2b, 2c, etc. “per length unit” can be stacked in the stacking direction X in relation to the x-y-z coordinate system in FIG. 1a.

The housings 2a-2d can be designed as a plug-in connector housing for a plug-in connector 102 put together in a disc-like or modular-like manner. However, they can also be designed as a clamp housing. The advantage for the respective housing is stackability into a combined unit of housings which are connected to one another at least in a latching manner. The housings can moreover also be connected to one another in a clamping manner.

The housings 2a-2d furthermore have one or more—in this case four—narrow sides 23, 24, 25, 26 in addition to the main housing side walls 21 and 22.

If the housings 2a-2d are plug-in connector housings, they can have, on one narrow side 23, at least one or more conductor terminal contacts (not shown here) and preferably have, on an opposing narrow side 25, at least one or more plug-in contacts (not shown here), which can be conductively connected to one another in the respective housing.

In order to connect the housings 2a, 2b, 2c and 2d to one another in the stacked state to form the housing arrangement 1, corresponding connection mechanisms that have at least one first latching connection that possesses corresponding latching mechanisms are provided on the housings 2b, 2c, 2d. These corresponding latching mechanisms can together form a first latching hook connection 3.

To realize the first latching hook connection 3, the respective housing 2c can have, as the first latching mechanism, at least one resiliently deflectable latching arm 31 with a latching aperture 314. The further housing 2b stacked thereon can have on the same narrow side 24 as the latching arm 31 at least one fixed protrusion-like latching hook 32 as a second corresponding latching mechanism, which corresponds to the latching arm 31 with the latching aperture 314 (FIG. 2a, 3a).

The respective latching hook 32 can have a chamfer 321 and a latching edge 322.

The first housing 2a and the cover plate 2e of the housing arrangement may in each case have only one of these latching mechanisms. Thus, the first housing 2a of the housing arrangement 1 can only have the latching hook 32 and the last housing 2e can only have a latching arm 31′, with the latching arm 31′ here being formed differently from the remaining latching arms 31.

The resiliently deflectable latching arm 31 of the housings 2b, 2c, 2d, is on one of the narrow sides 23-26 of these housings 2b, 2c, 2d, 2e.

The resiliently deflectable latching arm 31 of the housings 2b, 2c, 2d, is preferably on one of the two narrow sides 24, 26 on which no conductor terminal and no plug-in contact are formed.

The resiliently deflectable latching arm 31 of the housings 2b, 2c, 2d, is preferably on that narrow side 24 of the housings 2b, 2c, 2d, which is at the top in FIG. 1a.

The latching arm 31 can be integrally connected to the remaining housing in a connecting region 311.

Starting from this connecting region 311, the latching arm 31 extends at least in the case of the middle housings 2b, 2c, 2d in a first arm region 312 parallel to the narrow side 24 above these in a direction perpendicular to the stacking direction X. The latching arm 31 then has a lug 313 (as a second arm region) which extends in or against the stacking direction and in which the latching aperture 314 is formed.

The resiliently deflectable latching arm 31 has a relatively long length perpendicular to the stacking direction X starting from its connecting region 311 up to the end of the lug 312, and is therefore able to be deflected relatively far in the Z-direction upwards or away from the housing 2b, 2c, etc. When adjacent housings—e.g. 2b, 2c—of the housing arrangement are plugged together, the latching arm can be deflected relatively far when it hits the latching hook 32 by sliding along the chamfer 321 of the latching hook 32 by its lateral edge until it finally slips over the latching hook 32 and securely latches onto this with the latching aperture 314.

It is particularly advantageous that the latching arm 31 be longer than if it or a deflectable other latching hook 31 would extend only in the stacking direction. It is possible that the latching arm 31, starting from the connecting region 311 up to the latching aperture 314, be longer than the screen width d of the housings 2 in the stacking direction (see FIGS. 1b, 2c and 2g).

The lug 313 can extend in the stacking direction x over approximately half of the width of the housing narrow side 24. The latching arm 31 preferably has a type of recess 315 (see FIG. 1a), in which the lug 313 of the respectively stacked housing 2 can engage when the stacked-together housings 2 are stacked and plugged together. In the corresponding other half of the housing narrow side 24, the respective latching hook 32 can then be formed on the narrow side 24 as a type of protrusion.

One or more optional and differently formed latching hook connections 4 can support fixing the adjacent housings 2a, 2b.

Moreover, one or more mortise joints 5, which act preferably in a centering and clamping manner, can optionally and additionally be provided between the stacked-together housings 2a, 2b, 2c and 2d (see FIG. 2f, for example).

To realize the additional latching hook connections 4, the first stacking wall 21 of a respective housing 2b can have at least one protruding latching hooks 41 as a first latching mechanism, and the second stacking wall 22 of the respective next housing 2c can have at least one latching aperture 42 as the second corresponding latching mechanism corresponding to the latching hook 12 with a latching undercut.

To realize the clamping connections 5, the first stacking wall 21 of a respective housing 2b can have at least one protruding clamping mortises 51 as a first clamping mechanism, and the second stacking wall 22 of the respective next housing 2c can have at least one clamping aperture 52 as the second corresponding clamping mechanism corresponding to the clamping mortise 51 (see FIG. 2a, 2e, 3a).

The latching arm 31′ of the optional cover plate 2e, starting from a base plate region 2e, can transition via a 180° bending and connecting region 311′ into a lug 313, in which an additional latching aperture 314 is provided. The 180° bending region makes it possible to nevertheless give this latching hook 31 sufficient length such that it can simply latch onto a latching hook 32 of the corresponding adjacent housing 2d (see FIGS. 3a-3l).

It can also be envisaged that the housings 2 of the housing arrangement 1 have one of the latching connections 3 on opposing narrow sides in each case, as inferred from FIGS. 2a and 3a. In this manner, the housings 2 of the housing arrangement 1 can be securely connected to one another. The first housing 2a, the “middle” housings 2b to 2d and the lateral cover plate 2e then preferably have “identical” latching arms 31, 31′ and latching hooks 32 on the top and bottom of the narrow sides 24 and 26 which are virtually symmetrical to a middle plane. In this respect, one, more or all of the features of the above “top” latching connections 3 on the housings 2 can additionally be implemented on the bottom narrow sides 26 of the housings 2.

A housing arrangement 1 is provided in which at least one latching hook connection 3 of the respective stacked-together housings 2a, 2b can be latched particularly simply and formed very securely. It should be remarked that not all features of the figures have to be realized in every exemplary embodiment. For instance, the cover plate 2e is optional and the latching arms 31 and latching hooks 32 can be formed geometrically differently than depicted. It is possible to provide no inclined edges 316. Additional geometrical changes can be realized as long as there is no departure from the scope and spirit of the invention.

What is claimed is:

1. A housing arrangement comprising at least two or more interconnected housings stacked together in a stacking direction and having at least one receiving space respectively in which one or more electrical component, electronic component, or both are arranged, the respective housings having a disc-like configuration, two stacking walls and a plurality of narrow sides, adjacent housings of the housing arrangement being connected to one another with at least one latching connection, wherein the latching connection of at least a middle housing of the housing arrangement has at least one latching arm extending at one of the narrow sides in an arm region parallel to the narrow side starting from a connecting region in which it is connected to the respective housing, the latching arm having a lug extending in the stacking direction and engaging at least in part over an adjacent housing and a first latching mechanism for latching on a corresponding second latching mechanism of an adjacently stacked housing.

2. The housing arrangement according to claim 1, wherein the lug has a latching aperture as a first latching mechanism.

3. The housing arrangement according to claim 2, wherein the latching aperture has a window configuration that fully penetrates the lug.

4. The housing arrangement according to claim 1, wherein the second latching mechanism includes a projection-like and immovable latching hook arranged on the respective housing narrow side and on which the latching arm is also formed.

5. The housing arrangement according to claim 4, wherein the latching hook has a chamfer for raising a latching arm of an adjacent housing when housings are pushed together, the latching hook further having a latching edge on which the latching aperture can be engaged.

6. The housing arrangement according to claim 4, wherein the lug has a lateral chamfer which facilitates lifting the lug when adjacent housings of the housing arrangement are pushed together.

7. The housing arrangement according to claim 3, wherein a length of the latching arm from the connecting region to the latching aperture (314), is greater than a screen width of the housings of the housing arrangement in the stacking direction.

8. The housing arrangement according to claim 1, wherein middle housings of the housing arrangement each have one of the latching connections on opposing narrow sides.

9. The housing arrangement according to claim 4, and further comprising a cover plate arranged to close off one side of the housing arrangement and on which there is a latching hook configured to latch onto one of the housing projection-like latching hooks.

10. The housing arrangement according to claim 4, wherein a first housing of the housing arrangement has one of the projection-like latching hooks.

11. The housing arrangement according to claim 4, wherein at least one of one or more additional latching hook connections having a configuration that differs from the latching hook of the second latching mechanism are arranged between adjacent housings and one or more mortise joints are arranged between the housings for centering and clamping.

12. A plug-in connector having a housing arrangement according to claim 1.

13. A series terminal having a housing arrangement according to claim 1.
